(19) United States
(12) Patent Application Publication
(10) Pub. No.: US 2007/0037345 A1
(43) Pub. Date: Feb. 15, 2007

(54) Memory cell array and memory cell

(76) Inventor: Dirk Manger, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/203,404

(22) Filed: Aug. 15, 2005

(51) Int. Cl. H01L 21/8242

(52) U.S. Cl. 438/239; 257/E27.086

(57) ABSTRACT

A method of forming a memory cell array including a plurality of memory cells includes patterning isolation trenches on a semiconductor substrate and filling with an insulating material to define active area lines. In particular, the isolation trenches are patterned as straight lines, resulting in the active area lines being formed as straight lines. After forming word lines incorporating a plurality of gate electrodes, isolation grooves are formed by etching the semiconductor substrate material using the gate electrodes as an etching mask. The active area segments are isolated from each other by a self-aligned etching step. Thereafter, the transistors are completed by defining the first and second source/drain regions, and the remaining parts of the memory cells, in particular, the capacitor contacts, the bit lines and the storage capacitors are formed.

### FIELD OF THE INVENTION

The invention further relates to a memory cell array including plurality of memory cells such as, for example, DRAM (dynamic random access memory) cells, as well as a method of forming the memory cell array.

### BACKGROUND

Memory cells of a dynamic random access memory (DRAM) generally include a storage capacitor for storing an electrical charge, which represents information to be stored and an access transistor connected with the storage capacitor. The access transistor includes first and a second source/drain regions, a channel connecting the first and second source/drain regions as well as a gate electrode controlling an electrical current flowing between the first and second source/drain regions. The transistor usually is at least partially formed in a semiconductor substrate. The portion in which the transistor is formed generally is denoted as the active area. The gate electrode forms part of a word line, and it is electrically isolated from the channel by a gate dielectric. By addressing the access transistor via the corresponding word line, the information stored in the storage capacitor is read out. In particular, the information is read out to a corresponding bit line via a bit line contact.

In the currently used DRAM cells, the storage capacitor can be implemented as a trench capacitor in which the two capacitor electrodes are disposed in a trench that extends in a substrate in a direction perpendicular to the substrate surface.

In another implementation of the DRAM memory cell, the electrical charge is stored in a stacked capacitor, which is formed above the surface of the substrate. A problem associated with DRAM memory cells including stacked capacitors is that it is necessary to electrically isolate adjacent active areas, which are assigned to one row of memory cells, from each other.

In addition, a DRAM cell array having a higher packaging density is generally desirable. For example U.S. Pat. No. 6,545,904, the disclosure of which is incorporated herein by reference in its entirety, discloses a memory cell including an access transistor and a storage capacitor, which can be formed so as to implement a 6F² (6 F×F) DRAM array. In particular, two neighboring access transistors are arranged so that they have a common bit line contact. In addition, neighboring access transistors formed on a single active area line are electrically isolated from each other by an isolation gate line.

Moreover, DE 199 28 781 C1 discloses a 6 F² memory cell in which two adjacent memory cells share one common bit line contact. Two neighboring pairs of memory cells which are formed in one active area line are separated and electrically isolated from each other by a groove which is filled with an isolating material.

In addition, H. S. Kim at al., “An outstanding and highly manufacturable 80 nm DRAM technology”, IEDM 2003, discloses a memory cell array in which two adjacent memory cells share one common bit line contact. The storage capacitor is implemented as a stacked capacitor. Neighboring active areas, which are assigned to one row of active areas, are electrically insulated from each other by an isolation groove, the length of this isolation groove being very large.

Moreover, when scaling down the structural feature size F of the memory cell for reducing the area needed for a memory cell, the distance between the heavily doped source/drain regions shrinks resulting in a problem with the data retention time, i.e., the time during which information is recognizably stored in the storage capacitor. To maintain the distance between the first and the second source/drain regions while reducing the typical feature size, recessed channel array transistors have been proposed.

### SUMMARY

In accordance with one embodiment of the invention, a method of forming a memory cell array comprises the following steps: providing a semiconductor substrate including a surface; defining a plurality of isolation trenches in the surface of the semiconductor substrate that laterally confine a plurality of active areas in which transistors are to be formed, one active area being laterally confined by two isolation trenches, respectively; filling the isolation trenches with an isolating material; providing a plurality of word lines intersecting the active areas, each of the word lines being insulated from the active areas by a gate insulating material; providing a plurality of isolation grooves, the isolation grooves being configured to insulate neighboring active areas from each other, the isolation grooves intersecting the isolation trenches; providing a plurality of transistors which are at least partially formed in the active areas, each of the transistors comprising a first and a second source/drain region, a channel connecting the first and second source/drain region and a gate electrode forming part of a corresponding one of the word lines; providing a plurality of storage capacitors on the surface of the semiconductor substrate, each of the storage capacitors comprising a storage electrode, a counter electrode and a capacitor dielectric; connecting each of the storage electrodes with a corresponding one of the first source/drain regions; providing a plurality of bit lines, a plurality of second source/drain regions being connected with a corresponding one of the bit lines. The step of providing the isolation grooves further comprises the steps of covering predetermined portions of the substrate surface with a masking material, etching the semiconductor substrate at portions of the substrate surface that are not covered with word lines or with the masking material, and filling the isolation grooves with an isolating material.

Initially, isolation trenches are patterned and filled with an insulating material, thereby defining active area lines. In particular, the isolation trenches are patterned as straight lines, resulting in the active area lines being formed as straight lines. After defining the word lines incorporating a plurality of gate electrodes, the isolation grooves are formed by etching the semiconductor substrate material using the gate electrodes as an etching mask. As a consequence, the active area segments are isolated from each other by a self-aligned etching step. Thus, advantageously, an isolation groove having a small width can be provided. As a result, the packaging density of the memory cells can be increased. The isolation grooves are formed so as to intersect the isolation trenches. In other words, the isolation grooves are not parallel with the isolation trenches. For example, the isolation trenches can be perpendicular with respect to the isolation grooves.

In addition, according to the present invention the first source/drain regions are formed at a position adjacent to the isolation groove. Advantageously, the first source/drain regions are formed after the step of defining the isolation grooves and filling the isolation grooves with an insulating material. Moreover, it is preferred that two memory cells are formed in one active area segment, the two memory cells sharing one common bit line contact.

According to the present invention, it is preferred that the word lines are covered with an isolating layer at a top side and the lateral sides thereof. In addition, it is preferred that this isolating layer is removed at least from the lateral sides of the word lines. Thereafter, a capacitor contact is formed at a position between the isolation groove and the remaining portion of the isolating layer.

Moreover, it is more preferable that the isolating layer, which is present on the top side of the word lines, comprises first and a second layers, where the second layer is provided on top of the first layer, the first layer being in contact with the gate electrode, and where the second layer can be selectively etched with respect to the first layer. Subsequently, an etching step is performed to selectively etch the second layer, so as to form the capacitor contact having well defined horizontal boundaries.

In accordance with another embodiment of the present invention, a memory cell array comprises memory cells, each of the memory cells comprising a storage capacitor and a transistor, and a semiconductor substrate, wherein active areas, isolation trenches and isolation grooves are formed in the semiconductor substrate. Each of the active areas includes a length along a first direction and a width along a second direction, the length being larger than the width. The isolation trenches are adjacent to the active areas and extend in the first direction, while the isolation grooves are adjacent to the active areas and extend in the second direction. The isolation trenches and the isolation grooves are configured to electrically isolate neighboring active areas from each other. The transistors are at least partially formed in the active areas and electrically couple corresponding storage capacitors to corresponding bit lines via bit line contacts, the transistors being addressed by the word lines. The following relation holds between the length L of the active areas and the distance D between neighboring active areas, the distance being measured in the first direction: D<0.287*L.

Due to the small distance between neighboring active areas of the memory cell array of the present invention, the packaging density of the memory cell array can advantageously be increased.

In addition, it is preferred to implement the storage capacitors as stacked capacitors, which are formed above the surface of the substrate. In particular, it is preferred to arrange the storage capacitors in a checkerboard pattern in which the capacitors are arranged in rows, the capacitors of the rows having an uneven row number being arranged in a first grid, the capacitors of the rows having an even row number being arranged in a second grid, and the first and the second grid being offset to each other, so that the capacitors of the even rows are disposed at half of the pitch of the capacitors of the uneven rows and vice versa. An advantage is thus obtained, in which a checkerboard layout is easier to implement in terms of the lithographical steps employed. In addition, by using such a pattern of capacitors, the packaging density of the capacitors can be further increased.

In accordance with a further embodiment of the present invention, a memory cell comprises a semiconductor substrate including a surface, a storage capacitor comprising a storage electrode, a capacitor dielectric and a counter electrode, the storage capacitor being formed above the surface of the semiconductor substrate, a transistor comprising a first and a second source/drain region, a channel connecting the first and second source/drain region and a gate electrode that is configured to control the conductivity of the channel, the first and the second source/drain regions forming part of the semiconductor substrate and a first direction being defined by the direction of the channel, and a bit line contact for connecting the second source/drain region with a corresponding bit line. The storage electrode of the storage capacitor is connected with the first source/drain region via a capacitor contact, the capacitor contact comprising a vertical portion extending perpendicular with respect to the substrate surface and a horizontal portion extending in the first direction parallel to the substrate surface. The bit line contact comprises only a vertical portion extending perpendicular with respect to the substrate surface.

By providing capacitor contacts having such an angled shape, the geometric arrangement of the capacitors and the connection thereof with the transistors is further simplified.

The above and still further objects, features and advantages of the present invention will become apparent upon consideration of the following detailed description of specific embodiments thereof, wherein like numerals designate like components in the drawings.

### BRIEF DESCRIPTION OF THE DRAWINGS

FIG. 1 is a plan view of the top surface of a semiconductor substrate with active area lines and isolation trenches that is used to form a memory cell array in accordance with the present invention.

FIG. 2A is a cross-sectional view of the semiconductor substrate of FIG. 1 after further processing to form the memory cell array in accordance with the present invention, where the left hand portion of FIG. 2A is taken perpendicular with respect to the word lines between dashed lines I and Ia as shown in FIG. 2B, and the right hand portion of FIG. 2A is taken perpendicular to an active area between dashed lines II and II as shown in FIGS. 1 and 2B.

FIG. 2B is a plan view of the top surface of the semiconductor substrate of FIG. 1 after further processing to form the memory cell array in accordance with the present invention.

FIG. 3 is a cross-sectional view of the semiconductor substrate of FIG. 2 after further processing to form the memory cell array in accordance with the present invention, where the view of FIG. 3 is taken perpendicular with respect to the word lines between dashed lines I and Ia as shown in FIG. 2B.

FIG. 4 is a cross-sectional view of the semiconductor substrate of FIG. 3 after further processing to form the memory cell array in accordance with the present invention, where the view of FIG. 4 is taken perpendicular with respect to the word lines between dashed lines I and I as shown in FIGS. 1 and 2B.

FIGS. 5 and 6 illustrate cross-sectional views of a memory cell array formed in accordance with a second embodiment of the present invention, where the views of FIGS. 5 and 6 are taken perpendicular with respect to the word lines between dashed lines I and Ia as shown in FIG. 2B.

FIG. 7 is a cross-sectional view of the semiconductor substrate after further processing to form the memory cell array in accordance with the present invention, where left hand portion of FIG. 7 is taken between dashed lines I and I as shown in FIG. 2B, and the right hand portion of FIG. 7 is taken perpendicular with respect to an active area between dashed lines III and III as shown in FIG. 2B.

FIGS. 8 and 9 are cross-sectional views of the semiconductor substrate of FIG. 7 after further processing to form the memory cell array in accordance with the present invention, where the views of FIGS. 8 and 9 are taken perpendicular with respect to the word lines between dashed lines I and I as shown in FIGS. 1 and 2B.

FIG. 10 is a cross-sectional view of the semiconductor substrate of FIG. 9 after further processing to form the memory cell array in accordance with the present invention, where left hand portion of FIG. 10 is taken between dashed lines I and I as shown in FIG. 2B, and the right hand portion of FIG. 10 is taken between dashed lines VI and VI as shown in FIG. 2B.

FIG. 11A is a cross-sectional view of the semiconductor substrate of FIG. 10 after further processing to form the memory cell array in accordance with the present invention, where left hand portion of FIG. 11A is taken between dashed lines VIII and VIII as shown in FIG. 2B, and the right hand portion of FIG. 10 is taken between dashed lines II and II as shown in FIG. 2B.

FIG. 11B is a plan view of a memory cell array in accordance with the present invention.

FIGS. 12A and 12B respectively depict a cross-sectional view and a plan view of a completed memory cell array in accordance with a first embodiment of the present invention.

FIG. 12C is a cross-sectional view of a completed memory cell array in accordance with a second embodiment of the present invention.

FIG. 13 depicts an exemplary electrical schematic of a memory cell array in accordance with the present invention.

### DETAILED DESCRIPTION

In the following description of the invention, reference is made to the accompanying drawings, in which are illustrated exemplary embodiments. It is noted that directional terminology such as “top”, “bottom”, “front”, “back”, “leading”, “trailing”, etc., is used with reference to the orientation of the figures being described. Because components of embodiments of the present invention can be positioned in a number of different orientations, the directional terminology is used solely for purposes of illustration of the embodiments in the figures and in no way is the invention to be considered limiting to such exemplary orientations of the figures. It is to be understood that other embodiments may be utilized and structural or logical changes can be made without departing from the scope of the present invention. The following description of exemplary embodiments, therefore, is not to be taken in a limiting sense, and the scope of the present invention is defined by the appended claims.

In accordance with the present invention, a memory cell array is formed by first providing a semiconductor substrate, such as a silicon substrate, which can be p-doped. In a first step, the active area lines are defined by patterning isolation trenches. For example, isolation trenches 12 can be photolithographically patterned using a mask having a lines/spaces pattern. In particular, the line width and the width of the spaces can be 1 F, wherein F denotes the minimal structural feature size or ground rule of the technology employed. For example, F can be 100 nm, and less, in particular 80 nm, 75 nm, 65 nm or even smaller dimensions. The isolation trenches 12 are etched so as to have a depth of approximately 220 nm or greater, if F is 80 nm. This depth can potentially be reduced for smaller ground rules. Thereafter, the isolation trenches 12 are filled, for example, by performing a thermal oxidation step for providing a silicon dioxide layer (not shown), optionally, depositing a thin silicon nitride layer (not shown), followed by a silicon dioxide layer (not shown). Finally, the isolation trenches are completely filled with an isolating material 32. Then, a planarizing step is performed.

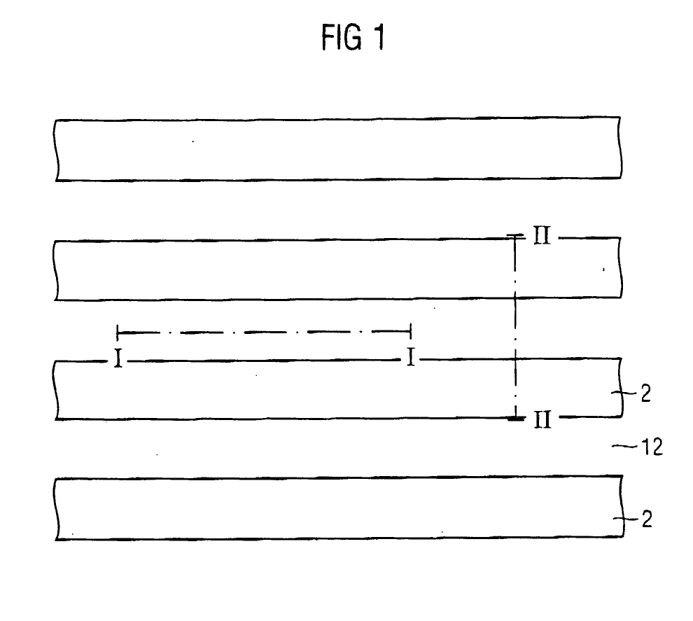

A plan view on the resulting structure is shown in FIG. 1, showing active area lines 2, which are delimited by isolation trenches 12. In other words, two active area lines 2 delimit one isolation trench 12, whereas two isolation trenches 12 delimit one active area line 2.

In the next step, implantation is performed to provide the doped well portions. Then, a silicon dioxide layer 86 forming a gate oxide layer is deposited, followed by the layer stack for forming the gate electrode. In particular, the gate electrode 85 is made of a layer stack including a tungsten silicide/polysilicon bilayer of a polysilicon layer having a thickness of 60 nm followed by a WSiₓ layer having a thickness of 40 nm for the 80 nm ground rule. Thereafter, a silicon nitride layer 80 having a thickness of approximately 100 nm is deposited at a ground rule of 80 nm. In the next step, the word lines are photolithographically patterned using a mask having a lines/spaces pattern. In particular, the word lines are patterned so that they have a line width of 1 F and a distance of 1.6 F. Thereafter, a sidewall oxide is thermally grown on the sidewalls of the word lines. In addition, a Si₃N₄ spacer 81 is formed, for example, by conformally depositing a silicon nitride layer on the whole surface, followed by an anisotropic etching step for removing the horizontal portions of the silicon nitride layer, leaving the vertical portions thereof, which form the spacer 81. In particular, the thickness of the spacer is approximately 0.6 F.

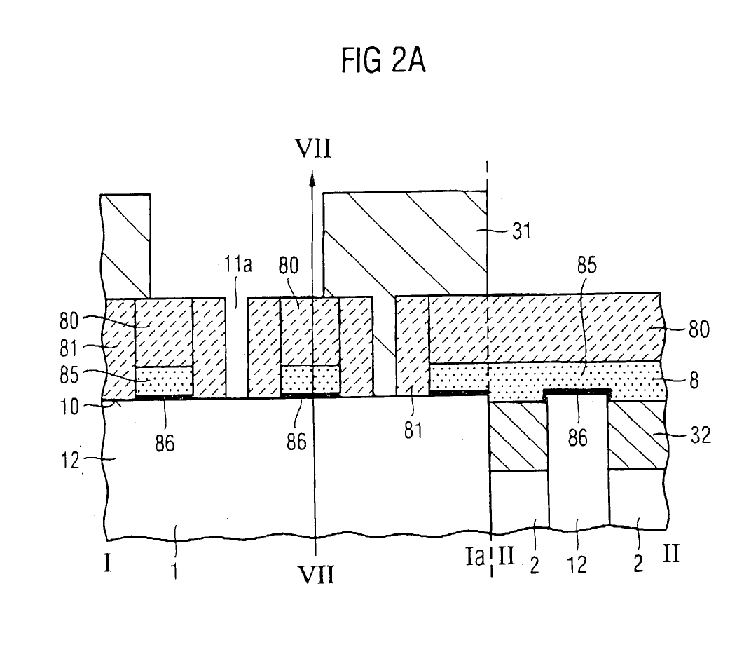

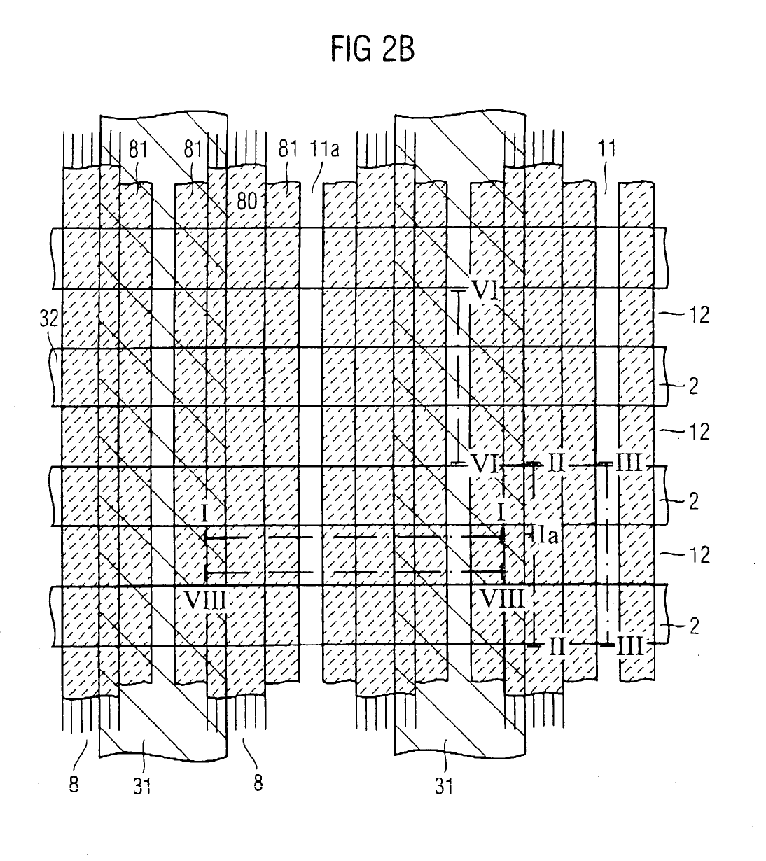

Thereafter, a photoresist material 31 is applied on the resulting surface and photolithographically patterned using a mask having a lines/spaces pattern. In particular, the photoresist material is patterned so as to cover every second opening between adjacent word lines and part of the adjacent word lines, while leaving every second opening 11a between neighboring word lines and a portion of the adjacent word lines uncovered. The resulting structure is shown in FIG. 2A, wherein the left hand portion of this view shows a cross-sectional view which is taken perpendicular with respect to the word lines between I and Ia as can be taken from FIG. 2B. In addition, the right hand portion of this view shows a cross-sectional view perpendicular to an active area 12 between II and II as can be taken from FIGS. 1 and 2B. In particular, the cross-sectional view between II and II intersects the view depicted in the left hand side of FIG. 2A at VII.

As can be seen from FIG. 2A, a plurality of gate electrodes 85 forming part of the word lines thus formed are arranged on the surface 10 of the semiconductor substrate 1. The gate electrodes 85 are electrically isolated from the substrate material by the gate isolating layer 86. On top of the gate electrodes 85, a Si₃N₄ cap layer is provided, whereas the sidewalls of the gate electrodes 85 are covered with a Si₃N₄ spacer 81. On top of the silicon nitride layer 80, stripes of a photoresist material 31 are provided so as to partially cover the Si₃N₄ cap layer 80 provided on the gate electrodes 85.

In particular, every second gap between some neighboring gate electrodes is covered with the photoresist material 31, and every second gap between other neighboring gate electrodes is uncovered. At the covered gap the bit line contact is to be formed, whereas at the uncovered gap 11a the capacitor contact is to be formed.

In the cross-sectional view between II and II, active areas 12 are provided, and isolation trenches 2 laterally delimit each of the active areas 12. The isolation trenches 2 are filled with an isolating material 32. A word line 8 is provided, the word line being isolated from the active area 12 by a gate-isolating layer 86. The word line is covered with a Si₃N₄ cap layer 80.

In addition, FIG. 2B shows a plan view on the resulting structure. As can be seen, active areas 12 and isolation trenches 2 are arranged in an alternating manner in a first direction. In addition, word lines 8 are arranged in a second direction, which is perpendicular to the first direction. Adjacent to the word lines 8, Si₃N₄ spacers 81 are provided.

A photoresist layer 31 is provided and patterned so as to form stripes that extend along the second direction. As can be taken from FIG. 2B, the stripes of photoresist material 31 cover every second gap between certain neighboring word lines and part of the neighboring word lines, whereas every second gap between other neighboring word lines, in particular, the isolation gap 11a, is uncovered. In addition, as can be seen from FIG. 2B, a portion of the cap layer, which is adjacent to the isolation gap 11a, is left uncovered as well.

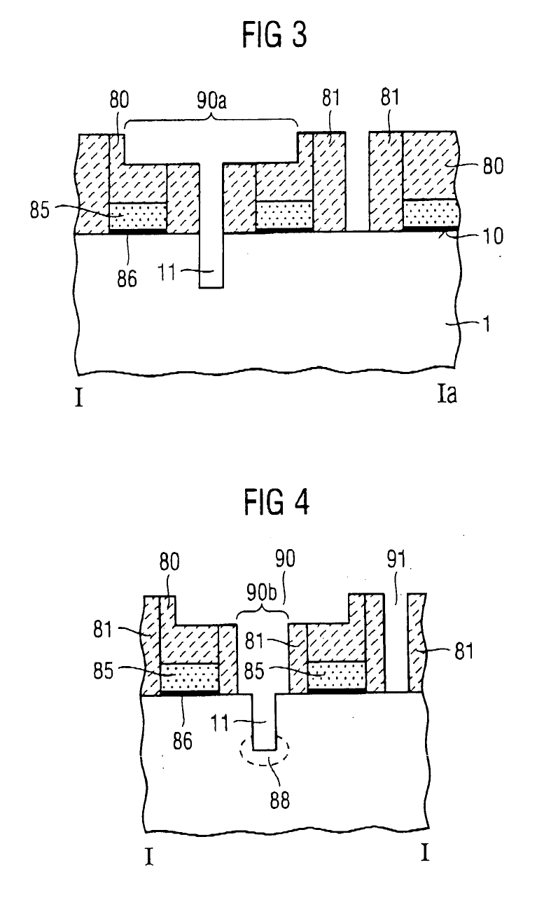

Taking the stripes of the photoresist material 31 as an etching mask, an anisotropic etching step for etching silicon selectively with respect to SiO₂ is performed. As a consequence, part of the silicon nitride cap layer 80 and of the silicon nitride spacers 81 is etched. In addition, the isolation groove 11 is etched in the silicon substrate 1 as is shown in FIG. 3. In particular, the isolation groove extends to a depth of about 90 to 250 nm. In addition, a short isotropic etching step for etching silicon selectively with respect to SiO₂ and SiN is performed. Then, the photoresist material 31 is removed from the surface. The resulting structure is shown in FIG. 3.

As can be seen, an isolation groove 11 is formed in the gap between two gate electrodes 85. In addition, part of the Si₃N₄ cap layer 80 and the Si₃N₄ spacer 81 which is directly adjacent to the isolation groove 11 is etched. Thereby, the opening 90a is formed in the Si₃N₄ cap layer 80. In part of the opening 90a the horizontal portion of the capacitor contact will be formed. As can be seen, the isolation groove 11 is formed in a self-aligned manner with respect to the gate electrodes 85.

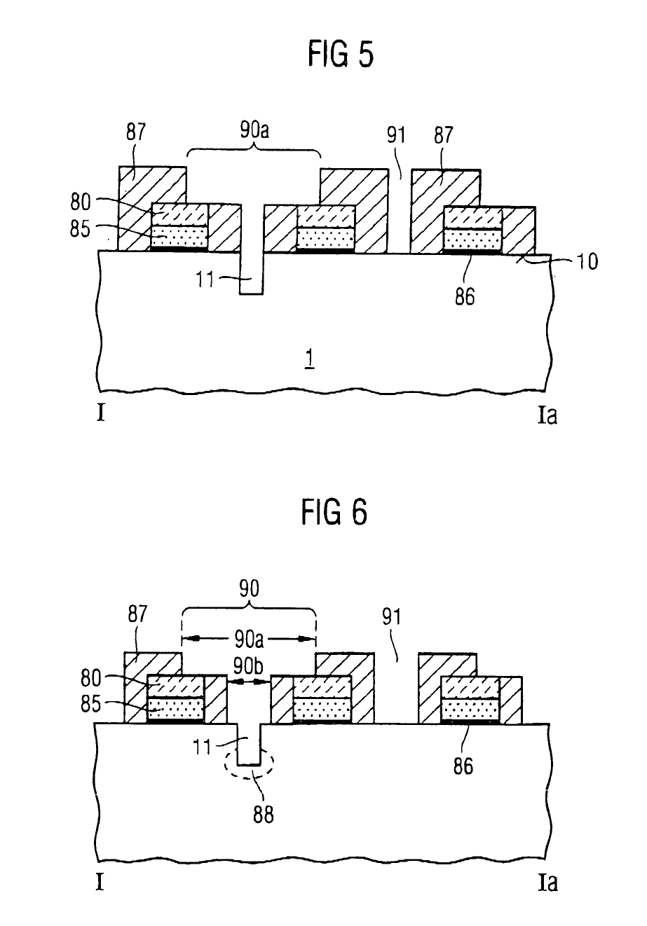

Thereafter, an isotropic Si₃N₄ etching step, which is selective with respect to Si and SiO₂, is performed. This etching step can be a dry or a wet etching step. In addition, optionally, an anti-punch implant for providing the implanted portion 88 can be performed. In particular, B, BF₂ or In can be used as a dopant. The p-doped portion 88 will prevent a leakage current from flowing between neighboring first source/drain regions, which are to be formed adjacent to the isolation groove 11. The resulting structure is shown in FIG. 4.

As can be seen, now the diameter of the opening 90b formed in the silicon nitride material 81 is enlarged with respect to the isolation groove 11. In addition, the diameter of the opening for 91 for forming the bit line contact is enlarged as well.

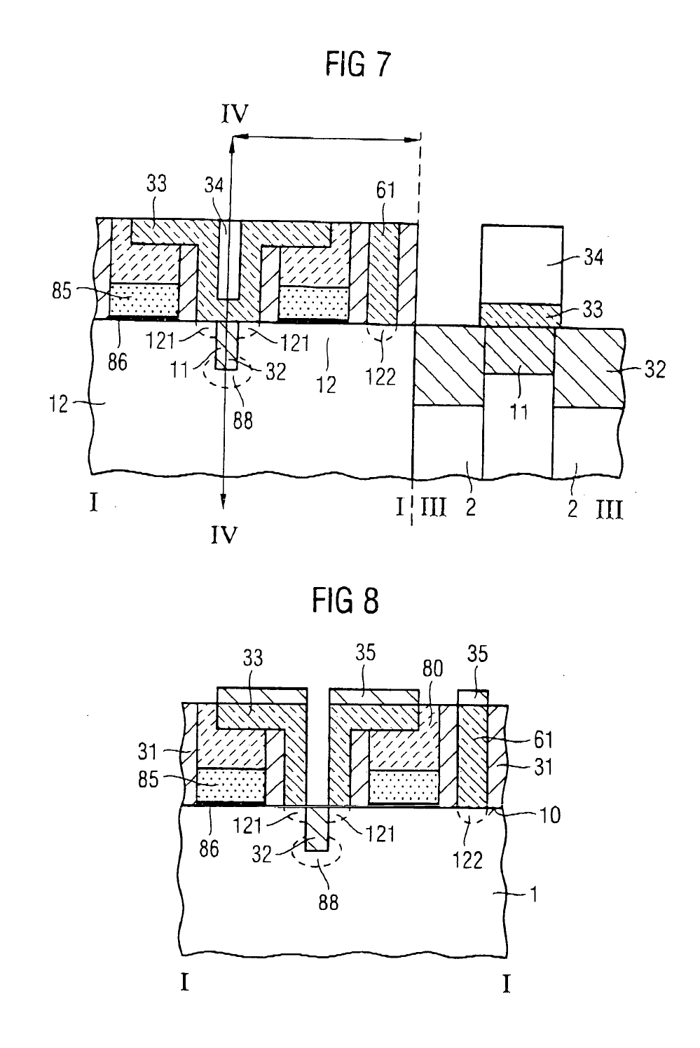

FIGS. 5 and 6 show cross-sectional views of the substrate according to a second embodiment of the present invention after performing the process steps, which have been described with reference to FIGS. 3 and 4, respectively. According to the second embodiment of the present invention, after depositing a silicon nitride cap layer 80 on the conductive material for forming the gate electrodes, a second masking layer 87, which can for example be made of SiOₓN_{y} and preferably having a high Si content, is deposited on the surface of the Si₃N₄ layer 80. After patterning the layer stack in the manner as has been described above so as to form the word lines, a spacer made of SiOₓN_{y} 87 is formed. The SiOₓN_{y} layer can be etched selectively with respect to Si₃N₄ and the SiO₂ material, which is present in the isolation trenches 2. One skilled in the art will recognize that the SiOₓN_{y} layer can be replaced with any other layer, which can be etched selectively with respect to SiO₂ and Si₃N₄.

For providing the isolation groove and the capacitor contacts, first an anisotropic Si etching step is performed that is selective with respect to SiO₂ and Si₃N₄. By this etching step, the SiOₓN_{y} layer 87 is etched as well, stopping on the Si₃N₄ layer 80. For example, if the SiOₓN_{y} 87 layer has an excess of silicon, it can be etched in aqueous ammonia, i.e. NH₄OH/H₂O. Thereafter, a short isotropic Si etching step, which is selective with respect to SiO₂, Si₃N₄ and SiON is performed. Then, the photoresist material 31 is removed. The resulting structure is shown in FIG. 5. As can be seen from FIG. 5, the openings 90a for forming the horizontal portions of the capacitor contacts have been formed by the anisotropic SiON etching step. The openings 90a have a well-defined bottom side, which is disposed at the boundary between the SiON layer and the Si₃N₄ layer 80. The depth of the opening 90a is an important feature of the capacitor contact to be formed, since this depth determines the resistance of the capacitor contact. In addition, as can be seen from FIG. 5, the isolation groove 11 has been formed by the Si etching steps described.

Thereafter, an isotropic etching step for etching SiON selectively with respect to Si, SiO₂ and Si₃N₄ is performed. This etching step can be a dry or a wet etching step. Then, optionally, an implantation step for providing a p-doped portion 88, for example with B, BF₂ or In can be performed. The resulting structure is shown in FIG. 6. As can be seen from FIG. 6, the thickness of the SiON layer 87 has been reduced. In addition, the diameter of the opening 90 has been increased, in particular in the lower portion 90b thereof. In other words, the diameter of the lower portion of the opening 90b now is greater than the diameter of the isolation groove 11. In addition, the diameter of the opening 91 for the bit line contact has been increased. The isolation groove 11 extends to a depth of approximately 90 to 250 nm and, in particular, 200 nm.

In the next step, according to the first and second embodiments of the present invention, which have been described with reference to FIGS. 3 and 4 and FIGS. 5 and 6, respectively, a SiO₂ layer is conformally deposited so as to provide an insulating filling 32 of the isolation groove 11. Thereafter, an etching step for etching the filling 32 back is performed. This etching step can be a wet or a dry, in particular an isotropic, etching step. In the next step, the implantation step for providing the heavily doped portions of the first and second source/drain regions 121, 122 is performed. For example, this implantation step is performed with As or P ions. Thereafter, a conductive material is filled in the openings 90 and 91 so as to form the corresponding contacts. In particular, it is preferred to first deposit a polysilicon layer, followed by a germanium layer which acts as a sacrificial layer for electrically isolating adjacent capacitor contacts. Alternatively, a tungsten layer can be deposited instead of the Ge layer. Thereafter, a lithographic step is performed in order to remove the conductive material from the isolation trenches 2. To be more specific, a lines/spaces pattern is patterned in a direction parallel to the direction of the active areas.

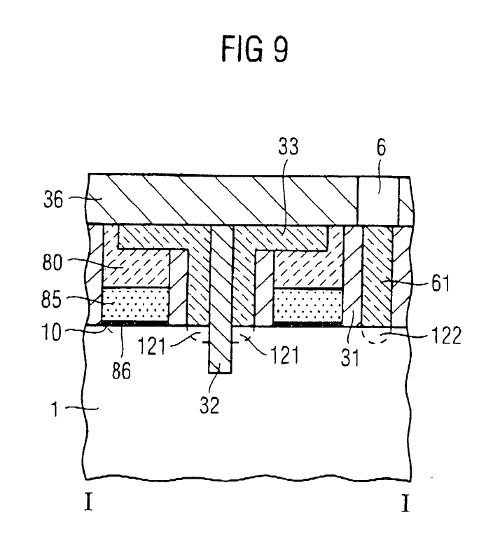

The resulting structure is shown in FIG. 7. The left-hand portion of FIG. 7 shows a cross-sectional view between I and I, as taken from FIG. 2B. In addition, the right-hand portion of FIG. 7 shows a cross-sectional view perpendicular with respect to an active area between III and III, as can be seen from FIG. 2B. In particular, the cross-sectional view on the right-hand side of FIG. 7 is made across the isolation groove 11 at position IV. In the left-hand portion of FIG. 7, it is shown that segments of active areas 12 are isolated by the isolation groove 11, which is filled with an isolating material 32. First source/drain regions 121 are formed directly adjacent to the isolation groove 11. As can be seen, a polysilicon landing pad 33 is formed in contact with the first source/drain region 121, two adjacent polysilicon landing pads 33 being separated by the sacrificial filling 34. In addition, the second source/drain region 122 is provided, the second source/drain region being in contact with the bit line contact 61, which extends perpendicular with respect to the substrate surface 10. As can be seen from the right hand portion of FIG. 7, the isolation groove 11 completely insulates adjacent segments of active areas from each other. The isolation groove 11 intersects the isolation trenches and, for example, can extend perpendicular to the isolation trenches. The conductive material 33 is insulated from the substrate portion between III and III, and it is covered with the sacrificial layer 34.

In the next step, an oxidation step (e.g., a thermal oxidation step) is performed. For example, a thermal oxidation step can be performed at a temperature higher than 800° C. in a chlorine containing or chloric ambient environment. As a consequence, a silicon dioxide layer 35 is formed on the polysilicon portions. In addition, GeO₂ and GeOCl₂, both of which are not stable, are formed on top of the Ge material. To be more specific, the GeO₂ and GeOCl₂ thus formed desorbs and is solved from the surface of the Ge layer, e.g., in a manner as described in the Journal of Electronic Materials, Vol. 33, No. 4, 2004, the disclosure of which is incorporated herein by reference in its entirety. In order to remove the stable phase GeO₂ which might also be formed, a rinse in dilute HCl/H₂O can be performed, as is also described in CRC Handbook of Chemistry and Physics, 67^{th} edition, R C Weast, p. B92, the disclosure of which is incorporated herein by reference in its entirety. Thereafter, an etching step in H₂O₂ is performed so as to remove the remaining Ge material 34. Thereafter, an anisotropic Si etching step is performed so as to remove the remaining horizontal portion of the polysilicon layer 33a from the opening 90b. In addition, optionally, an additional implantation step can be performed so as to increase the doped portion 88.

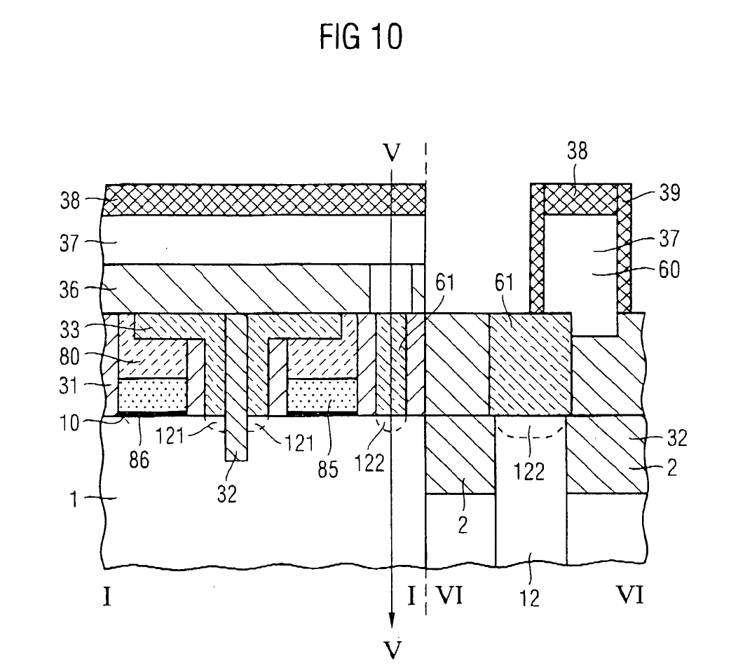

The resulting structure is shown in FIG. 8. As can be seen from FIG. 8, now the two adjacent landing pads 33 for the capacitor contact are isolated from each other. The landing pads 33 are covered with a silicon dioxide layer 35. Moreover, the bit line contact 61 is covered with the silicon dioxide layer 35.

In the next step, a SiO₂ layer is deposited so as to provide a SiO₂ filling 32 in the region above the isolation groove 11. Moreover, a SiO₂ layer 36 is provided on the surface of the structure shown in FIG. 8. Thereafter, the silicon dioxide layer 36 is photolithographically patterned using a mask having a line/spaces pattern. In particular, the layer 36 is patterned so as to form lines that are parallel with respect to the active areas and perpendicular to the word lines. Thereafter, an etching step for etching silicon dioxide selectively with respect to silicon is performed. Then, a bit line contact opening 6 is defined in the silicon dioxide layer 36. The resulting structure is shown in FIG. 9. As can be seen from FIG. 9, adjacent capacitor contact landing pads 33 now are insulated from each other by the SiO₂ filling 32. Moreover, a SiO₂ layer 36 is formed on the surface. Bit line contact openings 6 are formed so as to be in contact with the bit line contacts 61.

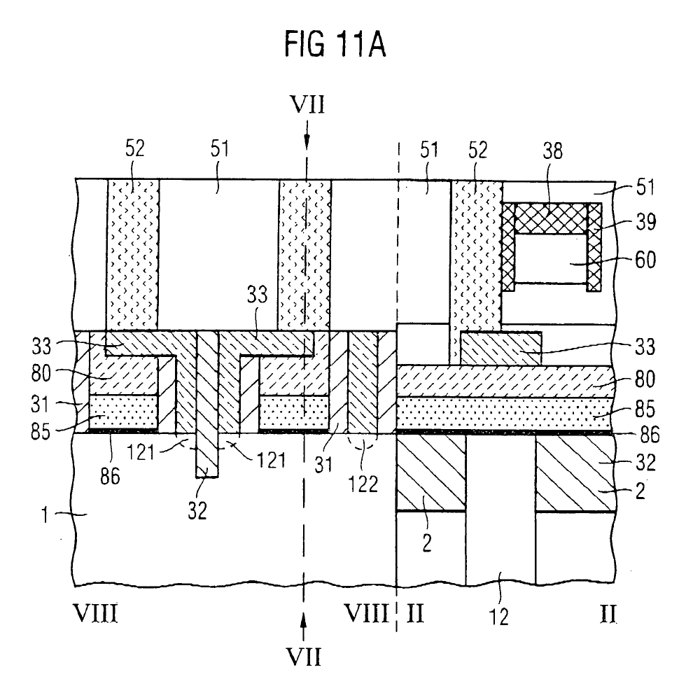

In the next step, a metal layer 37 for forming the bit lines is deposited, followed by deposition of a Si₃N₄ layer 38. Thereafter, the MO layer stack is patterned using a mask having a lines/spaces pattern so as to form lines that are parallel to the active areas and perpendicular with respect to the word lines. An etching step is performed, followed by steps for forming a Si₃N₄ spacer. In particular, a silicon nitride layer is conformally deposited and, thereafter, it is anisotropically etched so as to remove the horizontal portions thereof, thereby forming a Si₃N₄ spacer 39. The resulting structure is shown in FIG. 10.

As can be seen from FIG. 10, bit lines 60 are formed, the bit lines extending in the direction of the active areas 12. The bit line 60 is in contact with the second source/drain region 122 via the bit line contact 61. This is also shown in the right hand portion of FIG. 10 between VI and VI which is taken across the bit line contact 61. In particular, the cross-section between VI and VI is taken perpendicular to the view between I and I at position V in the left hand portion of FIG. 10.

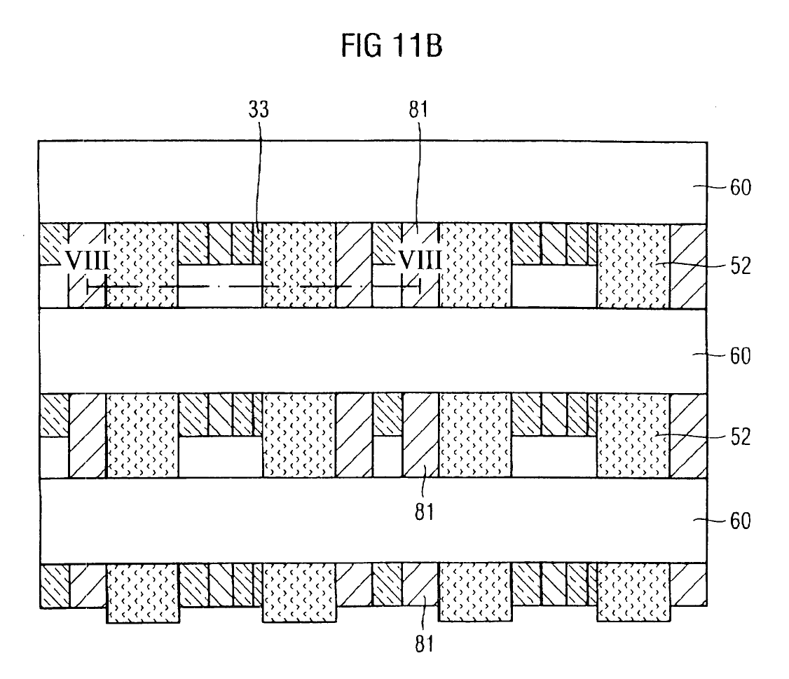

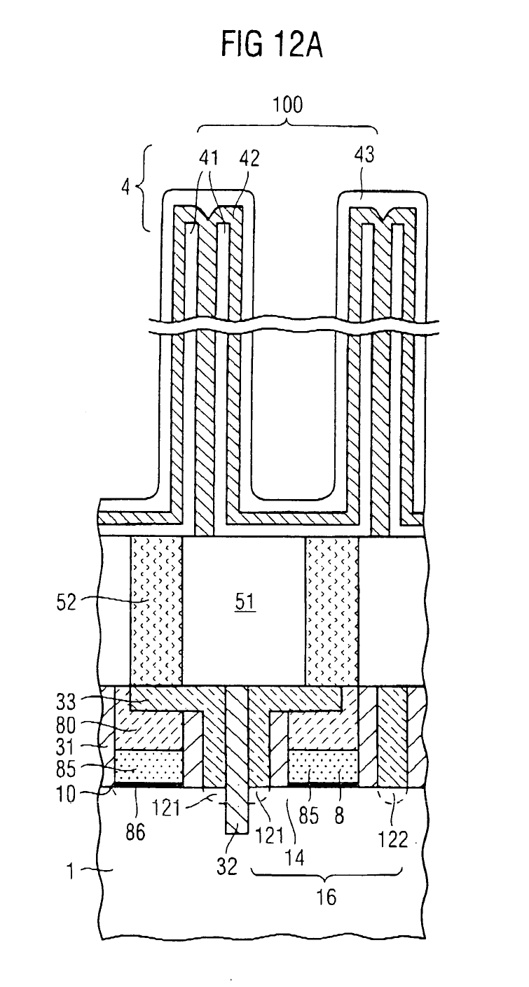

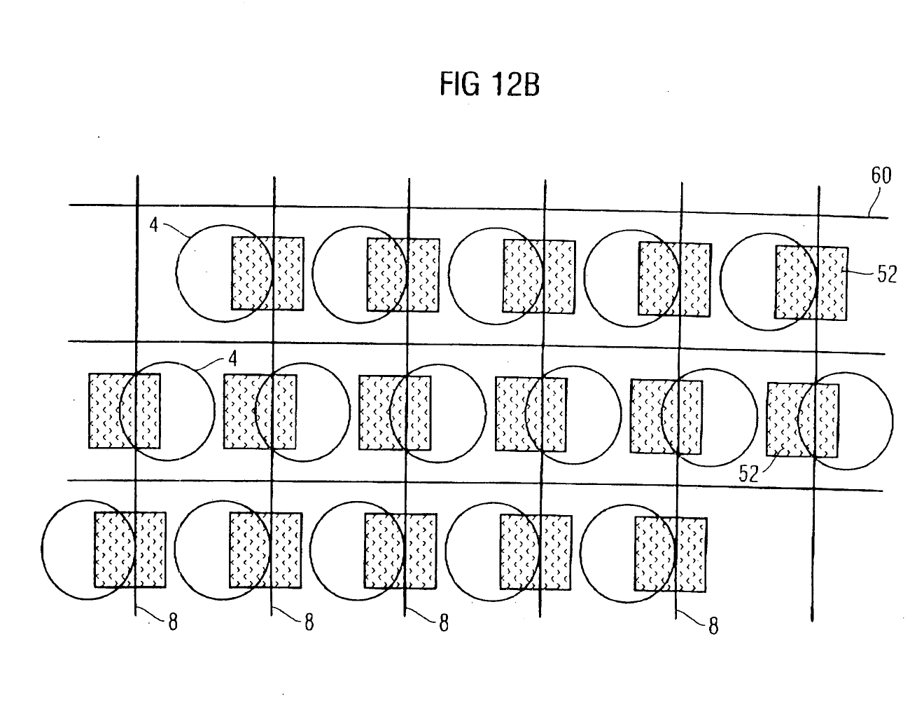

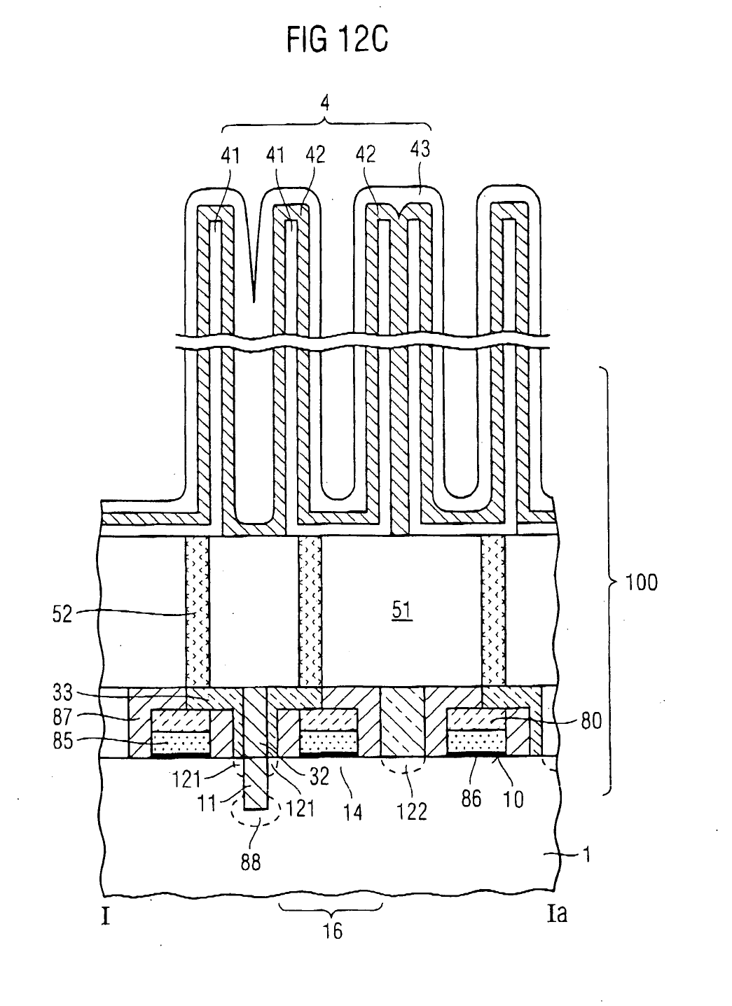

In the next step, a further silicon dioxide filling 51 is provided, and a CMP (chemical mechanical polishing) step is performed so as to obtain a planarized surface. This SiO₂ filling 51 fills the gap between adjacent bit lines 37. Since the bit lines 37 are not located above the active areas so as to cover them entirely, as can also be taken from the cross-sectional view between VI and VI in FIG. 10, this silicon dioxide filling 51 fills the space on the left of the depicted bit line 37. Moreover, this silicon dioxide filling 51 is disposed over part of the active area 12. Thereafter, a lithographic step for forming capacitor contacts 52, which are connected with the landing pads 33, is performed. Then, an etching step for opening the capacitor contacts 52 is performed. This etching step is selective with respect to silicon nitride and the polysilicon material of the landing pads 33, so that the openings will directly land on the landing pads 33. The layout of these contact openings is chosen in accordance with the layout of the array of capacitors, which are to be formed. In particular, as will be explained with reference to FIG. 12B, the capacitors can be arranged in a checkerboard pattern. Thereafter, a conductive material is provided in the openings so as to form the capacitor contacts 52, followed by a CMP step. The resulting structure is shown in FIGS. 11A and 11B.

In particular, FIG. 11A shows a cross-sectional view between VIII and VIII, as can be taken from FIG. 2B, and a cross-sectional view between II and II, as can be taken from FIG. 2B, whereas FIG. 11B shows a plan view of the resulting structure. The view between II and II is taken perpendicular to the view between VIII and VIII at position VII. As can be seen from FIG. 11A, capacitor contacts 52 are formed so as to be in contact with the landing pads 33, which are connected with the first source/drain regions 121. Adjacent capacitor contacts 52 are insulated from each other by the silicon dioxide filling 51. The cross-sectional view between II and II shows a cross-sectional view of a landing pad 33, which is connected with the capacitor contact 52, a bit line 60 being partially disposed above the landing pad 33. In addition, as can be seen from FIG. 11B, the capacitor contacts 52 are formed in a pattern of a regular grid. Bit lines 60 are arranged in a first direction. The bit lines are positioned partially above the active areas, leaving space for forming capacitor contacts 52.

FIG. 12A shows a cross-sectional view of the completed memory cell. As can be seen, a stacked capacitor 4 comprising a storage electrode 41, a capacitor dielectric 42 and a counter electrode 43 are provided on the surface of the structure shown in FIG. 11A. In particular, the memory cell 100 includes a storage capacitor 4 and a transistor 16. The transistor 16 is implemented as a transistor having a planar channel, i.e. a channel, that essentially includes a horizontal channel. In particular, a current flowing between first and second source/drain regions 121, 122 mainly flows parallel to the surface 10 of the substrate 1. The first and second source/drain regions are disposed adjacent to the surface 10 of the semiconductor substrate 1. In addition, the gate electrode 85 is formed above the surface 10 of the substrate surface. The conductivity of the channel 14 is controlled by the gate electrode 85, which is electrically isolated from the channel by the gate isolating layer 86. When addressing a memory cell by activating a corresponding word line 8, the gate electrode 85 which forms part of the word line 8 opens the transistor and enables information stored in the storage capacitor 4 to be read out via the capacitor contact 52, the capacitor contact landing pad 33, the first source/drain region 121, the channel 14 and the second source/drain region 122, the bit line contact 61 to the corresponding bit line (not shown in this drawing).

FIG. 12B shows a plan view of the array of storage capacitors 4 formed in contact with the capacitor contacts 52. In particular, as is shown in FIG. 12B, the capacitors are arranged in a checker board pattern, i.e. the capacitors are arranged in rows so that the capacitors of two adjacent rows are arranged in a staggered manner, the capacitors of every even row being arranged in columns and the capacitors of every uneven row being arranged in columns as well, the first columns being in a space between two adjacent columns of the uneven rows, respectively. In other words, the capacitors of every row are arranged at a distance corresponding to a cell pitch. Neighboring rows are offset to each other by half of the cell pitch. The capacitor contacts 52 are arranged in a pattern of a grid. In addition, word lines 8 extending in a first direction and bit lines 60 extending in a second direction are provided. By arranging the capacitors in a checkerboard pattern, a high storage capacity can be achieved, while maintaining the surface area needed for the memory cells. Thus, the surface area of the memory cell array can be greatly exploited.

FIG. 12C shows a cross-sectional view of the completed memory cell according to the second embodiment of the present invention, in which the gate electrodes 85 are covered with the silicon nitride layer 80, a SiON layer 87 encapsulating the gate electrode 85/Si₃N₄ layer 80 stack. As can be seen from FIG. 12C, a memory cell 100 includes a storage capacitor 4 as well as a transistor 16. The transistor 16 includes a first and a second source/drain electrode 121, 122, a channel 14 connecting the first and the second source/drain electrodes and a gate electrode 85 which is disposed adjacent to the channel 14 and which is electrically insulated from the channel by a gate dielectric 86. A landing pad 33 for connecting the stacked capacitor 4 with the first source/drain region 121 is provided. Adjacent memory cells are insulated from each other by the isolation groove 11, which is filled with a SiO₂ filling 32. The first source/drain regions 121 are formed adjacent to the isolation groove 11. Due to the thickness of the SiON spacer 87 which is formed on the two sidewalls of the gate electrode 85, a distance between the heavily doped portions 121, 122 is increased so that an electrical field will not be too strong and, as a result, a leakage current is not enlarged even though the width of the gate electrode and, hence, a channel length is reduced. Since the landing pad 33 is formed by etching a bilayer stack including the silicon nitride layer 80 and the SiON layer 87, the shape of the landing pad 33 can be well defined so as to provide an excellent conductivity.

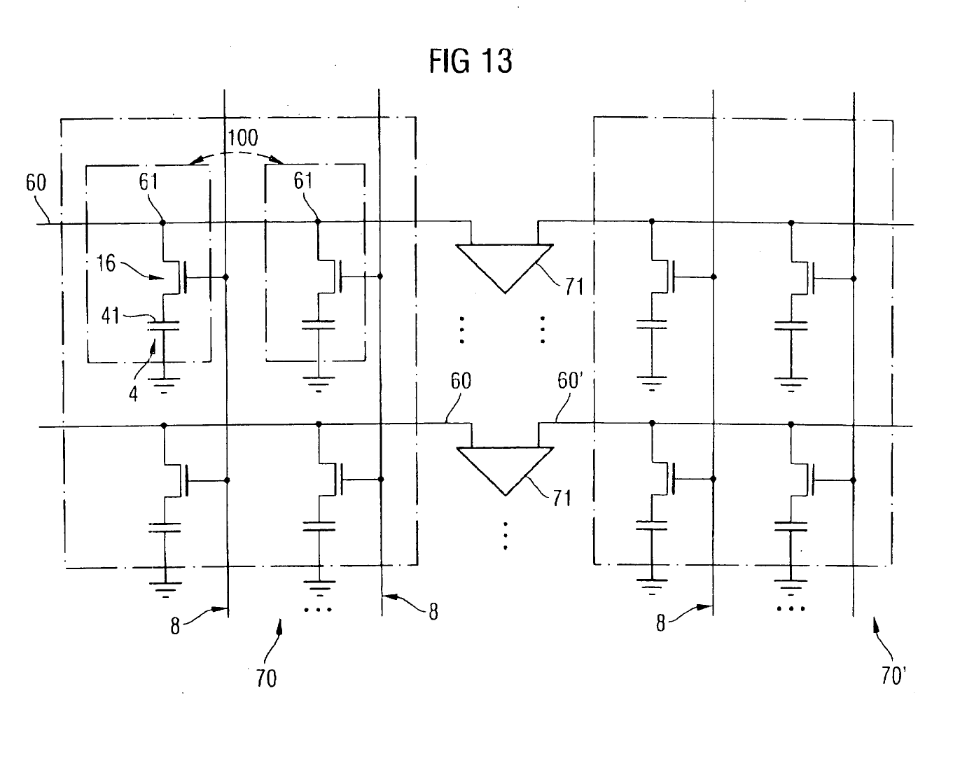

FIG. 13 shows a schematic view of part of a memory device incorporating a pair of the memory cell arrays 70, 70′, which can be obtained by the process steps described above, the memory cell array being implemented in an open-bit line configuration. As is shown in FIG. 13, a memory cell array comprises a plurality of memory cells 100 that are arranged in rows and columns, respectively. Each of the memory cells includes a storage capacitor 3 as well as a transistor 16, which is connected with the storage electrode 41 of the storage capacitor 4.

The bit lines 60, 60′ are arranged perpendicular with respect to the word lines 8, 8′, and the bit lines 60 are parallel to each other. Each of the bit lines 60 is connected with a plurality of second source/drain regions of the memory cells 100 via a bit line contact 61.

The memory cell arrays 70, 70′ are each coupled to respective groups of bit lines 60, 60′ and respective groups of word lines 8, 8′. The two groups of bit lines 60, 60′ are coupled, one from each of the memory arrays 70, 70′, to sense amplifiers 71. The sense amplifiers 71 include peripheral circuitry, i.e., circuitry employed in support of the memory cell arrays 70, 70′ and generally are formed outside of peripheries of the memory arrays 70, 70′.

In operation, one memory cell 100 is selected, for example, by activating one word line 8. The word line 8 is coupled to a respective gate electrode of a respective one of the transistors 16. The bit line 60 is coupled to the first source/drain region of one of these transistors 16 via the bit line contact 61. The transistor 16 is then turned on, coupling charge stored in the capacitor 4 to the associated bit line 60. The sense amplifier 71 then senses the charge coupled from the capacitor 4 to the bit line 60. The sense amplifier 71 compares that signal to a reference signal such as the reference charge Qref or a reference signal that is obtained by sensing a corresponding bit line 60′, without a voltage being applied to the corresponding word line 8′, amplifies the resulting signal and latches the amplified signal from appropriate duration. This allows data represented by the charge stored in the capacitor 4 to be accessed external to the memory arrays 100, 100′ and also allows the capacitor 4 to store charge representative of the data from the memory cell 100 back into the memory cell 100. One skilled in the art will clearly recognize that alternative array architectures, such as a vertically twisted bit line array architecture, can also be used in the present invention.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCES

1 semiconductor substrate
10 substrate surface
11 isolation groove
11a isolation gap
12 active area
121 first source/drain region
122 second source/drain region
14 channel
16 transistor
2 isolation trench
31 photoresist material
32 SiO₂ filling
33 polysilicon landing pad
33a polysilicon layer
34 sacrificial filling
35 SiO₂
36 SiO₂ layer
37 metal layer
38 Si₃N₄ cap layer
39 Si₃N₄ spacer
4 stacked capacitor
41 storage electrode
42 capacitor dielectric
43 counter electrode
51 SiO₂ filling
52 capacitor contact
6 bit line contact opening
60, 60′ bit line
61 bit line contact
70, 70′ memory cell array
71 sense amplifier
8, 8′ word line
80 Si₃N₄ cap layer
81 Si₃N₄ spacer
85 gate electrode
86 gate oxide
87 SiON layer
88 implanted portion
90 capacitor contact opening
90a top portion of the opening
90b bottom portion of the opening
91 bit line contact opening
100 memory cell

What is claimed:

1. A method of forming a memory cell array, comprising:
providing a semiconductor substrate including a surface;
forming a plurality of isolation trenches in the surface of the semiconductor substrate, the isolation trenches laterally confining a plurality of active areas in which transistors are to be formed, wherein a single active area is laterally confined by two neighboring isolation trenches;
filling the isolation trenches with an isolating material;
forming a plurality of word lines in the semiconductor substrate such that the word lines intersect the active areas and each of the word lines is insulated from the active areas by a respective gate insulating material;
forming a plurality of isolation grooves in the semiconductor substrate, the isolation grooves being configured to insulate each active areas from a neighboring active area, wherein the isolation grooves intersect the isolation trenches;
forming a plurality of transistors within the semiconductor substrate, the transistors being at least partially formed in the active areas, each of the transistors comprising a first source/drain region and a second source/drain region, a channel connecting the first and second source/drain regions and a gate electrode that forms part of word line corresponding with the transistor;
providing a plurality of storage capacitors on the semiconductor substrate surface, each of the storage capacitors comprising a storage electrode, a counter electrode and a capacitor dielectric;
connecting each of storage electrode with a first source/drain region of a corresponding transistor; and
forming a plurality of bit lines such that each bit line is connected with a plurality of corresponding second source/drain regions;
wherein the step of forming the plurality of isolation grooves comprises:
covering predetermined portions of the semiconductor substrate surface with a masking material;
etching the semiconductor substrate at portions of the semiconductor substrate surface that are not covered with the word lines and are not covered with the masking material; and
filling the isolation grooves with an isolating material.

2. The method of claim 1, wherein two memory cells are disposed in at least one active area between two neighboring isolation grooves.

3. The method of claim 2, wherein the first source/drain region of each of the memory cells is formed adjacent to a corresponding isolation groove.

4. The method of claim 1, wherein the plurality of word lines are covered with an isolating layer such that a top portion each word line is covered with an isolating cap layer and the sidewalls of each word line are covered with an isolating spacer layer, and the method further comprises:
removing a portion of the isolating spacer layer from each sidewall of each of the word lines so as to form an opening above a remaining portion of the isolating spacer layer at each sidewalls of each word line; and
filling a conductive material in each opening so as to form a capacitor contact within the opening above the remaining portion of the isolating spacer layer at each sidewall of each word line.

5. The method of claim 4, wherein the step of removing a portion of the isolating spacer layer from each sidewall of each of the word lines includes removing a portion of the cap layer from the top portion of each word line.

6. The method of claim 4, wherein the isolating cap layer comprises a first and a second layer, the second layer being disposed on top of the first layer and the second layer being selectively etchable with respect to the first layer.

7. The method of claim 1, wherein a width of each isolation groove is less than a width of each word line.

8. A memory cell array, comprising:
memory cells, each of the memory cells comprising a storage capacitor and a transistor; and
a semiconductor substrate including a surface, active areas, isolation trenches and isolation grooves formed in the semiconductor substrate, each of the active areas including a length L along a first direction of the semiconductor substrate and a width along a second direction of the semiconductor substrate, the length being larger than the width, each of the isolation trenches being adjacent to a respective active area and extending in the first direction and each of the isolation grooves being adjacent to a respective active area and extending in the second direction, the isolation trenches and the isolation grooves being configured to electrically isolate each active area from a neighboring active area, the transistors being at least partially formed in the active areas and electrically coupling corresponding storage capacitors to corresponding bit lines via bit line contacts, the transistors being addressed by the word lines;
wherein the memory cell array is configured such that the following relationship exists between the length L of the active areas and a distance D that is defined between neighboring active areas as measured in the first direction: D<0.287*L.

9. The memory cell array of claim 8, wherein the storage capacitors are formed above the semiconductor substrate surface, the storage capacitors being arranged in a plurality of rows, wherein a distance between two neighboring storage capacitors of one row corresponds to a cell pitch, and the storage capacitors of neighboring rows are offset in alignment with each other by half of the cell pitch.

10. The memory cell array of claim 8, wherein two memory cells are disposed in at least one active area between two neighboring isolation grooves.

11. The memory cell array of claim 8, wherein each of the transistors comprises a first source/drain region and a second source/drain region, a channel connecting the first and the second source/drain regions and a gate electrode configured to control the conductivity of the channel, and each of the storage capacitors comprises a storage electrode, a counter electrode and a capacitor dielectric, each storage capacitor being connected with a first source/drain region of a corresponding transistor via a capacitor contact, the capacitor contact comprising a vertical portion extending perpendicular with respect to the semiconductor substrate surface and a horizontal portion extending in the first direction parallel to the semiconductor substrate surface, and wherein each bit line contact connecting a second source/drain region with a corresponding bit line comprise only a vertical portion extending perpendicular with respect to the semiconductor substrate surface.

12. A memory cell, comprising:
a semiconductor substrate including a surface;
a storage capacitor comprising a storage electrode, a capacitor dielectric and a counter electrode, the storage capacitor being formed above the semiconductor substrate surface;
a transistor comprising a first source/drain region and a second source/drain region, a channel connecting the first and second source/drain regions and a gate electrode configured to control the conductivity of the channel, wherein the first and the second source/drain regions form part of the semiconductor substrate and the channel extends along a first direction of the semiconductor substrate; and
a bit line contact to connect the second source/drain region with a corresponding bit line;
wherein the storage electrode of the storage capacitor is connected with the first source/drain region of the transistor via a capacitor contact, the capacitor contact comprising a vertical portion extending perpendicular with respect to the semiconductor substrate surface and a horizontal portion extending in the first direction parallel to the semiconductor substrate surface, wherein the bit line contact comprises only a vertical portion extending perpendicular with respect to the semiconductor substrate surface.
